(19) United States
(12) Patent Application Publication
(10) Pub. No.: US 2009/0250719 A1
(43) Pub. Date: Oct. 8, 2009

(54) NITRIDE COMPOUND SEMICONDUCTOR DEVICE AND SEMICONDUCTOR LASER

(75) Inventor: Takao FUJIMORI, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/338,860

(22) Filed: Dec. 18, 2008

(30) Foreign Application Priority Data
Dec. 18, 2007 (JP) P2007-325766
Dec. 15, 2008 (JP) 2008-318488

(51) Int. Cl. H01L 33/00; H01L 29/20; H01S 5/323

(52) U.S. Cl. 257/103; 257/615; 257/E29.089; 257/E33.023; 372/44.01

(57) ABSTRACT

A nitride semiconductor device includes a semiconductor substrate composed of gallium nitride, and a stack which is provided on the semiconductor substrate and includes at least one nitride semiconductor layer containing aluminum, wherein substrate thickness T of the semiconductor substrate and a sum S of products of proportions of aluminum and thicknesses of all of the nitride semiconductor. layer containing aluminum among the stack satisfy a relationship of: T/860<=S<=T/530.

### CROSS REFERENCE TO RELATED APPLICATIONS AND INCORPORATION BY REFERENCE

This application is based upon and claims the benefit of priority from prior Japanese Patent Application P2007-325766 filed on Dec. 18, 2007 and prior Japanese Patent Application P2008-318488 filed on Dec. 15, 2008; the entire contents of which are incorporated by reference herein.

### BACKGROUND OF THE INVENTION

1. Field of the Invention

The present invention relates to a nitride semiconductor device and specifically relates to a nitride semiconductor device including nitride semiconductor layers containing aluminum and a semiconductor laser composed of the nitride semiconductor device.

2. Description of the Related Art

Semiconductor light emitting elements of semiconductor lasers (laser diodes), light emitting diodes (LEDs), and the like include nitride semiconductor devices each having layered nitride semiconductors. Such nitride semiconductors include aluminum nitride (AlN), gallium nitride (GaN), indium nitride (InN), Aluminum gallium nitride (AlGaN), and the like. A typical nitride semiconductor is expressed by AlₓIn_{y}Ga_{1-x-y}N (0<=x<=1, 0<=y<=1, 0<=x+y<=1).

An example of the semiconductor light emitting element composed of a nitride semiconductor device is described in Japanese Patent Laid-open Publication No. 2004-281432. On a semiconductor substrate, an n-type nitride semiconductor layer (an n-type semiconductor layer), a light emitting layer (an active layer), and a p-type nitride semiconductor layer (a p-type semiconductor layer) are stacked in this order. The semiconductor device outputs light generated by recombination of electrons supplied from the n-type semiconductor layer and holes supplied from the p-type semiconductor layer in the active layer.

However, the nitride semiconductor device including stacked nitride semiconductor layers is structurally subject to internal stress due to differences in thermal expansion coefficient and Young's modulus between adjacent nitride semiconductor layers. This internal stress causes stress in each nitride semiconductor layer and causes warpage and crack of the device. Such a problem is thought to become more notable when chips are miniaturized. Furthermore, stress to the active layer is an important parameter influencing the device characteristics, and the internal stress therefore causes degradation of the device characteristics.

### SUMMARY OF THE INVENTION

An aspect of the present invention is a nitride semiconductor device. The nitride semiconductor device includes a semiconductor substrate composed of gallium nitride; and a stack which is provided on the semiconductor substrate and includes at least one nitride semiconductor layer containing aluminum, wherein substrate thickness T of the semiconductor substrate and a sum S of products of proportions of aluminum and thicknesses of all of the nitride semiconductor layer containing aluminum among the stack satisfy a relationship of: T/860<=S<=T/530.

Another aspect of the present invention is a semiconductor laser. The semiconductor laser includes a semiconductor substrate composed of gallium nitride; and a stack which is provided on the semiconductor substrate and includes at least one nitride semiconductor layer containing aluminum, wherein substrate thickness T of the semiconductor substrate and a sum S of products of proportions of aluminum and thicknesses of all of the nitride semiconductor layer containing aluminum among the stack satisfy a relationship of: T/860<=S<=T/530, and a chip width vertical to a resonance direction of a laser beam and a thickness direction of the semiconductor substrate is not less than 60 μm and not more than 80 μm.

### BRIEF DESCRIPTION OF THE DRAWINGS

FIG. 1 is a schematic cross-sectional view showing a structure of a nitride semiconductor device according to an embodiment of the present invention.

FIG. 2 is a schematic view of a nitride semiconductor stack for explaining internal stress produced in each layer of the nitride semiconductor device.

FIG. 3 is a table showing Young's modulus and thermal expansion coefficients of nitride semiconductors.

FIG. 4 is a schematic view showing a simplified model for calculating internal stress produced in each layer of the nitride semiconductor device.

FIG. 5 is a graph showing a relation between stress and sum calculated using the simplified model shown in FIG. 4.

FIG. 6 is a graph showing stress and Al proportion calculated using the simplified model shown in FIG. 4.

FIG. 7 is a schematic view of a simplified model for calculating internal stress produced in each layer of the nitride semiconductor device.

FIG. 8 is a graph showing a relation between stress and substrate thickness calculated using the simplified model shown in FIG. 7.

FIGS. 9A to 9C are schematic views showing chip size of the nitride semiconductor device according to the embodiment of the present invention.

FIG. 10 is a schematic view showing a structure of the nitride semiconductor device according to the embodiment of the present invention.

### DETAILED DESCRIPTION OF THE INVENTION

An embodiment of the present invention will be described with reference to the accompanying drawings. In the following description of the drawings, the same or similar reference numerals are applied to the same or similar parts and elements. It is to be noted that the drawings are schematic and have different relationship between thickness and planer dimensions, proportions of thickness of layers, and the like from the real ones. Accordingly, specific thicknesses and dimensions should be determined with reference to the following description. Moreover, it is obvious that some parts have different dimensional relationships or proportions throughout the drawings.

The following embodiment just shows devices and methods to embody the technical idea of the present invention, and the technical idea of the present invention does not specify materials, shapes, structures, and arrangements of the constituent components and the like to the following description. The technical idea of the present invention can be variously modified in the scope of claims.

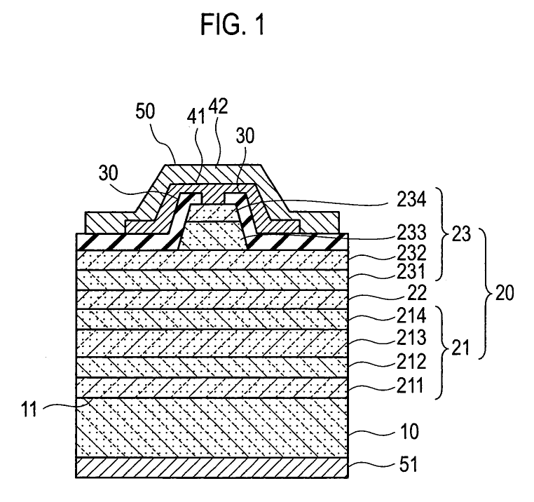

As shown in FIG. 1, a nitride semiconductor device according to an embodiment of the present invention includes: a semiconductor substrate 10 composed of gallium nitride; and a stack 20 which is provided on the semiconductor substrate 10 and includes at least one nitride semiconductor layer containing aluminum (Al). A sum S of products of proportions of Al and thicknesses of all the Al-contained nitride semiconductor layers included in the stack 20 and a substrate thickness T of the semiconductor substrate satisfy the relationship of the following equation (1):

T/860<=S<=T/530 (1)

For example, the sum S is a sum Σ(x*t), which is a sum of products of proportions x of Al and thicknesses t of all AlₓGa₁₋ₓN (0<x<=1) layers included in the stack 20.

As described above, the nitride semiconductor device is subject to internal stress due to the differences in thermal expansion coefficient and Young's modulus across the layers of the stack of the nitride semiconductor layer. Accordingly, in order to reduce the stress to the epitaxially grown layers including an active layer 22 due to internal stress, cracks caused by epitaxial growth, warpage of the nitride semiconductor layers, and the like, it is preferred to increase the substrate thickness T of the semiconductor substrate 10.

However, when the substrate thickness T is made thick, the smaller the chip size of the nitride semiconductor device is, the poorer the cleavage property is. This is because when the chip thickness is large compared to the chip width, cracks and notches tends to be caused in chips by cleavage or the chips cannot be separated along the cleavage planes. Accordingly, chip segmentation by cleavage is difficult.

Accordingly, as shown in equation (1), the sum S is controlled to not more than 1/530 of the substrate thickness T to reduce stress applied to the active layer 22, cracks, chip warpage, and the like while being controlled to not less than 1/860 of the substrate thickness T to keep good cleavage properties.

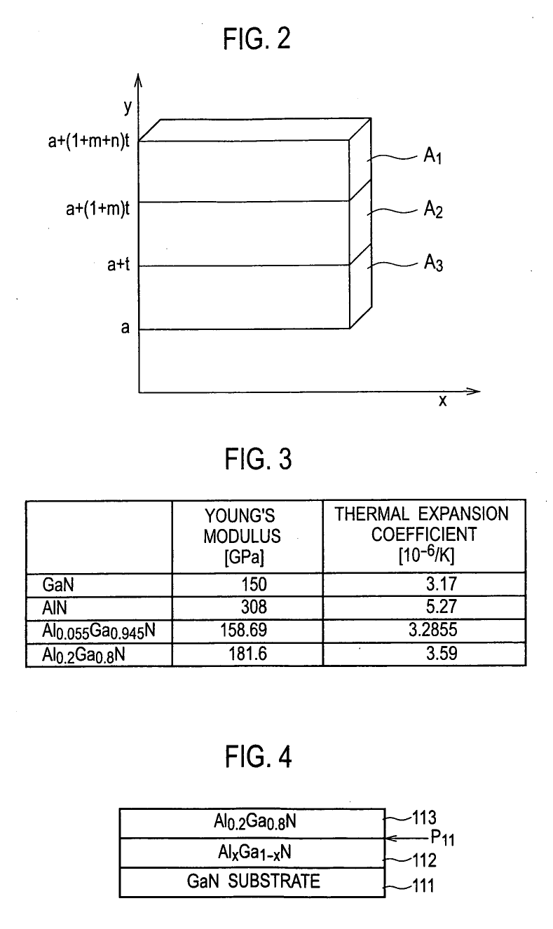

An explanation is given below of the internal stress caused in each layer of the nitride semiconductor device. For easy understanding, the explanation is made about stress produced in each layer in the case of a three-layer beam composed of first, second, and third layers A₁, A₂, and A₃ shown in FIG. 2. In FIG. 2, the fixed end of the beam is at the point of origin, and a direction that each layer extends is x-direction. The thickness direction in FIG. 2 is y-direction, and a y-coordinate of a bottom surface of the first layer A₁ is a coordinate a.

As shown in FIG. 2, thicknesses of the first to third layers A₁ to A₃ are t, m*t, and n*t, respectively. The first to third layers A₁ and A₃ have Young's modulus E₁ to E₃ and thermal expansion coefficients α₁ to α₃, respectively. The beam is not subjected to external force and has a uniform distribution of temperature.

When stress a due to variations in temperature is added based on Hooke's law for a one-dimensional bar, strain ε of the entire one-dimensional bar is expressed by equation (2):

ε=σ/E+αΔT (2)

In equation (2), E and α are the Young's modulus and thermal expansion coefficient of the one-dimensional bar, respectively and AT is a change in temperature. Equation (2) is solved for the stress a to obtain equation (3):

σ=E(ε−αΔT) (3)

In FIG. 2, the case of increasing the temperature by ΔT is considered, assuming that α₂>α₁. The strain ε at a y-coordinate η is expressed by equation (4) using a curvature radius ρ:

ε=η/ρ (4)

When equation (4) is substituted into equation (3), the stress σ is expressed by equation (5):

σ=E(η/ρ−αΔT) (5)

The Young's modulus and thermal expansion coefficient are different from layer to layer in the three-layer structure shown in FIG. 2. Precisely, equation (5) is expressed as the following equations (5a) to (5c):

σ=E₁(η/ρ−α₁ΔT): a<=η<=a+t (5a)

σ=E₂(η/ρ−α₂ΔT): a+t<=η<=a+(1+m+n)t (5b)

σ=E₃(η/ρ−α₃ΔT): a+(1+m)t<=η<=a+(1+m+n)t (5c)

Since the beam shown in FIG. 2 is not exposed to external force, axial force acting in a longitudinal direction of the beam and bending moment acting on the beam are both zero. Based on this condition, the thermal expansion coefficient α and curvature radius ρ are calculated as follows.

The axial force Nx is expressed by equation (6):

Nx: ∫_{A}σdA=0 (6)

Equation (6) is integrated for each layer of the three-layer structure to give equation (7):

∫_{A}σdA=∫_{A1}[{E₁(η/ρ−α₁ΔT)}b]dη+∫_{A2}[{E₂(η/ρ−α₂ΔT)}b]dη+∫_{A3}[{E₃(η/ρ−α₃ΔT)}b]dη (7)

The first term ∫_{A1}dη on the right-hand side of equation (7) indicates an integration from η=a to a+t; the second term ∫_{A2}dη, an integration from η=a+t to (1+m)t; and the third term ∫_{A3}dη, an integration from ηn=a+(1+m)t to a+(1+m+n)t.

The terms on the right-hand side of equation (7) are calculated as equations (8) to (10), respectively:

(First term): ∫_{A1}[{E₁(η/ρ−α₁ΔT)}b]dη=E₁b(a*t/ρ+t²/2ρ−α₁ΔTt) (8)

(Second term): ∫_{A2}[{E₂(η/ρ−α₂ΔT)}b]dη=E₂b(a*mt/ρ+mt²(1+m/2)/ρ−α₂ΔTmt) (9)

(Third term): ∫_{A3}[{E₃(η/ρ−α₃ΔT)}b]dη=E₃b[a*nt/ρ+t²*{2(m+1)n+n²}/2ρ−α₃ΔTnt] (10)

From equation (6), the sum of the first to third terms on the right-hand side of equation (7) equals to zero, and equation (11) is obtained for the curvature radius:

ρ={2(E₁+E₂m+E₃n)a+[E₁+E₂m(2+m)+E₃n{2(1+m)+n}]t}/{2ΔT(E₁α₂m+E₃α₃n)} (11)

The bending moment Mx is expressed by equation (12):

Mx: ∫_{A}(σ*η)dA=0 (12)

Equation (12) is integrated for each layer of the three-layer structure to give equation (13):

∫_{A}(σ*η)dA=∫_{A1}[{E₁(η/ρ−α₁ΔT)η}b]dη+∫_{A2}[{E₂(η/ρ−α₂ΔT)η}b]dη+∫_{A3}[{E₃(η/ρ−α₃ΔT)η}b]dη (13)

In equation (13), similar to equation (7), the first term ∫_{A1}dη on the right-hand side of equation (13) indicates an integration from η=a to a+t; the second term ∫_{A2}dη, an integration from η=a+t to (1+m)t; and the third term ∫_{A3}dη, an integration from η=a+(1+m)t to a+(1+m+n)t.

The first to third terms on the right-hand side of equation (13) are calculated as equations (14) to (16), respectively:

(First term): ∫_{A1}[{E₁(η/ρ−α₁ΔT)η}b]dη=E₁b{a²*t/ρ+(t²/ρ−α₁ΔTt)a−α₁ΔTt²/2+t³/3ρ} (14)

(Second term): ∫_{A2}[{E₂(η/ρ−α₁ΔT)η}b]dη=E₂b[{3a²*mt+(6m+3m²)*t²a+(3m+3m²+m³)t³}/3ρ−α₂ΔT{2mta+(2m+m²)t²}/2] (15)

(Third term): ∫_{A3}[{E₃(η/ρ−α₃ΔT)η}b]dη=E₃b[{nta²+(2+2m+n)nt²a+(1+2m+m²+n+nm+n²/3)nt³}/ρ−α₃ΔT{nta+(1+m+n/2)nt²}] (16)

From equation (12), the sum of the first to third terms on the right-hand side of equation (13) equals to zero, and equation (17) is obtained for the curvature radius ρ:

ρ=(A*a²+B*ta+E/3)/{ΔT(C*a+D/2*t)} (17)

Symbols A to E of equation (17) are values expressed by the following equations (18) to (22), respectively:

A=E₁+E₂m+E₃n (18)

B=E₁+E₂m(2+m)+E₃n{2(1+m)+n} (19)

C=E₁α₁+E₂α₂m+E₃α₃n (20)

D=E₁α₁+E₂α₂(2+m)m+E₃α₃(2+2m+n)n (21)

E=E₁+E₂m{3(1+m)+m²}+E₃n{3(1+m) (1+m+n)+n²} (22)

Equations (11) and (17) are solved for the coordinate a by eliminating the curvature radius p to give equation (23):

a=(4CD−3BE)t/{6(AE−BC)} (23)

Accordingly, the curvature radius ρ is calculated as equation (24):

ρ=2Aa+Bt/2ΔTC (24)

Equations (23) and (24) are substituted into equation (5) to give the stresses σᵢ applied to the first to third layers A₁ to A₃ as equation (25) (i=1 to 3):

$$\begin{matrix}{σ}_{i} = {E}_{i} ( η / ρ - {α}_{i} Δ T ) \\ = {E}_{i} [ η / \{ 2 Aa + Bt / ( 2 Δ TC ) \} - {α}_{i} Δ T ] \\ = {E}_{i} \{ η 2 Δ TC / ( 2 Aa + Bt ) - {α}_{i} Δ T \} \\ = {E}_{i} [ \begin{matrix}η \{ 2 Δ T ( \begin{matrix}{E}_{1} {α}_{1} + \\ {E}_{2} {α}_{2} m + {E}_{3} {α}_{3} n\end{matrix} ) \} / \\ \{ \begin{matrix}2 ( {E}_{1} + {E}_{2} m + {E}_{3} n ) a + \\ [ \begin{matrix}{E}_{1} + {E}_{2} m ( 2 + m ) + \\ {E}_{3} n \{ 2 ( 1 + m ) + n \}\end{matrix} ] t\end{matrix} \} - {α}_{i} Δ T\end{matrix} ]\end{matrix} \qquad ( 25 )$$

In the above description, for simplification of explanation, stress is calculated in the example of the three-layer and one-dimensional structure shown in FIG. 2. A multilayer three-dimensional structure is essentially no different from the three-layer one-dimensional structure. As shown by equation (25), stress produced in each layer is determined by the Young's modulus, thicknesses, and thermal expansion coefficients of the layers constituting the multilayer three-dimensional structure.

The Young's modulus and thermal expansion coefficient of especially AlGaN are greatly different from those of GaN. In a nitride semiconductor device including AlGaN layers and GaN layers, accordingly, the AlGaN layers greatly affects stress in each layer. GaN has a thermal expansion coefficient of 3.17×10⁻⁶ [K⁻¹] in the c-axis direction and a Young's modulus of about 150 [GPa]. Herein, the c-axis is an axis along a normal to c-plane, which is a polar plane of a hexagonal crystal structure of a nitride semiconductor. On the other hand, it is known that AlN has a thermal expansion coefficient of 5.27×10⁻⁶ [K⁻¹] in the c-axis direction and a Young's modulus of about 308 [GPa]. The thermal expansion coefficient and Young's modulus of AlGaN are intermediate values between those of AlN and GaN depending on the composition ratio thereof.

FIG. 3 shows examples of the Young's modulus and thermal expansion coefficient of nitride semiconductors. Indium nitride (InN) has a Young's modulus E₁ of about 105 [GPa] and a thermal expansion coefficient α₁ of about 3.15×10⁻⁶ [K⁻¹] in the c-axis direction. When the proportion of In is changed, a thermal expansion coefficient α_{I} and a Young's modulus E_{I} of InGaN change according to the proportion of In in InGaN (Vegard's law). The above Young's modulus E_{I} is calculated from an elastic constant.

The aforementioned calculation of stress revealed that AlGaN greatly affects internal stress produced in the nitride semiconductor device because of large differences in Young's modulus and thermal expansion coefficient across the materials thereof. The higher the proportion x of Al in an AlGaN layer is, the larger the internal stress is. Accordingly, as the proportion x of Al in the AlGaN layer becomes higher, the active layer and the like are subjected to larger stress or warpage, resulting in performance degradation and reduction of the lifetime of the nitride semiconductor device.

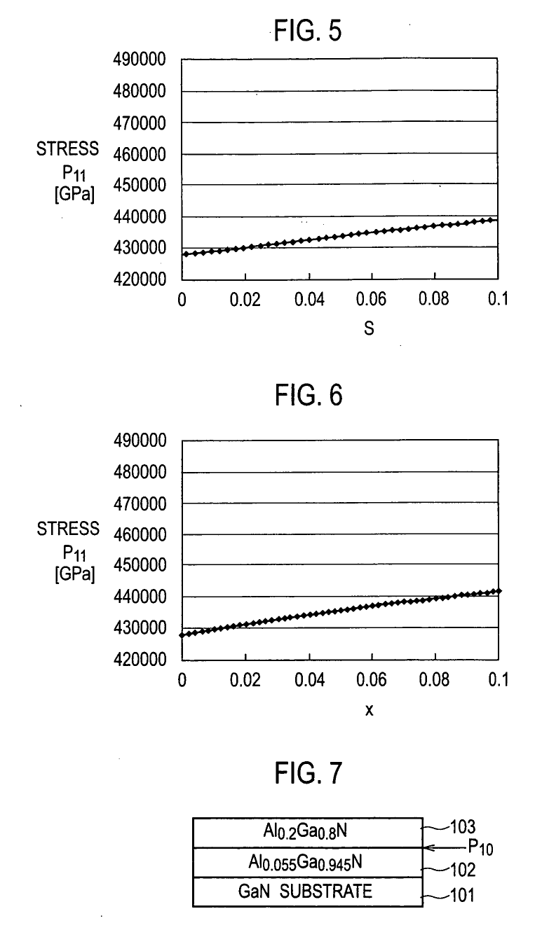

As described above, since the AlGaN layer greatly affects the internal stress, the calculation of the stress is performed using the simplified model shown in FIG. 4 with the other layers ignored. The simplified model shown in FIG. 4 has a structure including a 1.3 μm thick AlₓGa₁₋ₓN layer 112 and a 7 nm thick Al_{0.2}Ga_{0.8}N layer 113 stacked on a GaN substrate 111, in which stress P₁₁ acting between the AlₓGa₁₋ₓN layer 112 and the Al_{0.2}Ga_{0.8}N layer 113 is calculated. Changing the proportion x of Al of the AlₓGa₁₋ₓN layer 112 gives a relationship as shown in FIG. 5 between the stress P₁₁ and the sum S of products of the proportions and thicknesses. FIG. 6 shows a relationship between the proportion x of Al and stress P₁₁. This calculation results reveal that the stress P₁₁ linearly changes in response to a change in the sum S at least in a range of the sum S shown in FIG. 5.

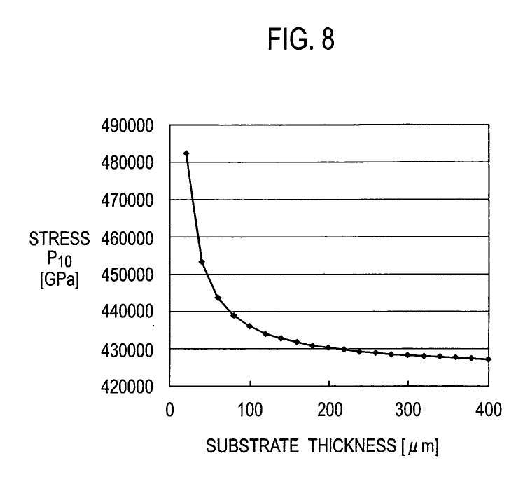

Using the simplified model shown in FIG. 7, the change in stress in response to the change in thickness of the substrate is calculated with the proportion of Al being unchanged. The simplified model shown in FIG. 7 has a structure including an Al_{0.055}Ga_{0.945}N layer 102 and a 7 nm thick Al_{0.2}Ga_{0.8}N layer 103 which are laid on the GaN substrate 101, in which stress P₁₀ acting between the Al_{0.055}Ga_{0.945}N layer 102 and the Al_{0.2}Ga_{0.8}N layer 103 is calculated. At this time, the sum S of products of the proportions and thicknesses is 0.0729 μm. FIG. 8 shows a relationship between the substrate thickness and the stress P₁₀. FIG. 8 reveals that the thinner the substrate is, the larger the stress applied to the AlGaN layer is while the thicker the substrate is, the smaller the stress applied to the AlGaN layer is. In other words, internal stress varies inversely with the substrate thickness T.

The condition required to produce smaller internal stress is making the substrate thicker. Herein, the internal stress is required to be not more than 449400 [GPa] which is a product of an asymptotic value (428000 [GPa]) of the internal stress for a thick substrate and a safety factor of 1.1. In this case, based on the calculation result, the substrate thickness T should be 50 μm or more.

In the embodiment of the present invention, the relationship between the sum S and the substrate thickness T is defined as follows. Specifically, for T=>50 μm, 50 μm is expressed with the sum S=0.0729 μm as 50 μm=685.8*S. The following equation (26) is thus established:

T=>685.8*S (26)

As the sum S increases, the entire stress accordingly increases. The substrate thickness T therefore should be increased according to the increase of the sum S for safety.

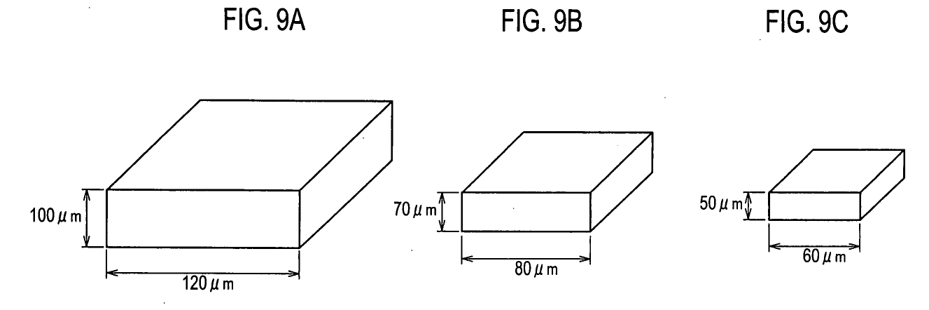

One of the purposes of the embodiment of the present invention is to implement a semiconductor laser with the chip size reduced. Specifically, in the case of a chip size (chip width) of 120 μm as shown in FIG. 9A, it is difficult to achieve good cleavage if the substrate thickness is 200 μm, for example. Making the substrate thickness smaller by abrasion can provide better cleavage. Accordingly, to achieve good cleavage, it is preferred to reduce the substrate thickness to a certain extent along with miniaturized nitride semiconductor devices. The output surface through which the laser beam is outputted, or the end of an oscillator of the semiconductor laser, is preferably a cleavage plane. Accordingly, as shown in FIG. 9A, the substrate thickness for a chip width of 120 μm is set to 100 μm. As shown in FIG. 9B, the substrate thickness for a chip size (chip width) of 80 μm is set to 70 μm. As shown in FIG. 9C, the substrate thickness for a chip size (chip width) of 60 μm is set to 50 μm. The chip thickness of a blue-violet laser diode described in Japanese Patent Laid-open Publication No. 2004-281432 is about 90 to 150 μm.

As described above, the substrate thickness T for a chip width of 60 to 80 μm should be not more than 70 μm. In the embodiment of the present invention, the relationship between the sum S and the substrate thickness T is defined as follows: for T<=70 μm, 70 μm is expressed with the sum S=0.0729 μm as 70 μm=960.2*S. The following equation (27) is thus established:

T<=960.2*S (27)

From equations (26) and (27), equation (28) is established:

T/960.2<=S<=T/685.8 (28)

The value of the sum S in the embodiment is, to be more specific, the sum S of products of the proportions and thicknesses of an n-clad layer, an electron block layer, and a p-clad layer, that is, S=0.1*0.002*100+0.3*0.03+0.1*0.002*100=0.069, which is substantially equal to the sum S of the above simplified model shown in FIG. 7 (=0.0729).

Moreover, in a semiconductor device described in Japanese Patent Laid-open Publication No. 2007-134445, for example, the value of the sum S is a sum of products of proportions and thicknesses of the n-clad layer, electron block layer, and p-clad layer: S=0.14*0.0025*200+0.2*0.01+0.14*0.0025*90=0.1035. The sum S often takes a value of about 0.07 to 0.10.

Since equation (28) is established for the sum S of 0.0729, in the light of a general range of the sum S or especially a general range including S=0.10, each side of equation (28) is multiplied with a coefficient 0.10/0.07, giving equation (29):

T/672.1<=S<=T/480.1 (29)

To satisfy both equations (28) and (29), it is necessary to satisfy the relationship of equation (30):

T/960.2<=S<=T/480.1 (30)

Equation (30) shows upper and lower limits of the calculation results, and the indicated range includes severe conditions. Accordingly, the condition range of S is defined with a margin of 10% (a factor of safety) as T/860<=S<=T/530.

When the sum S and substrate thickness T are selected so as to satisfy equation (1), it is possible to implement a semiconductor laser with less degradation of the device properties due to internal stress even if the substrate thickness is reduced along with decreasing chip size.

As already described, the higher the proportion x of Al in the AlGaN layer is, the larger stress or warpage the active layer and the like are subjected to, degrading the performance of the nitride semiconductor device and shortening the lifetime thereof. Accordingly, the relationship between the substrate thickness T of the-semiconductor substrate 10 composed of GaN and the thickness t and proportion x of Al in the AlGaN layer is important as shown in equation (1). In other words, stacking the nitride semiconductor layers on the GaN substrate so as to satisfy equation (1) can reduce the stress and warpage produced in the nitride semiconductor layers including the active layer.

A description is given below in detail of the structure of the nitride semiconductor device shown in FIG. 1. A stack 20 includes a structure in which an n-type semiconductor layer 21, the active layer 22, and a p-type semiconductor layer 23, each of which is composed of a nitride semiconductor, are sequentially stacked in this order. Light is generated from the active layer 22. As described later, each of the n-type semiconductor layers 21 and p-type semiconductor layer 23 includes nitride semiconductor layers containing Al.

The nitride semiconductor device shown in FIG. 1 further includes an n-side ohmic electrode 51 provided in contact with the rear surface of the semiconductor substrate 10 opposite to a substrate main surface 11; an insulating film 30 provided in contact with the upper surface (a surface opposite to the surface in contact with the active layer 22) of the p-type semiconductor layer 23; a p-side ohmic electrode 41 provided on the insulating film 30; and a p-side bonding electrode 42 provided on the p-side ohmic electrode 41. As shown in FIG. 1, the p-side ohmic electrode 41 is in contact with the p-type semiconductor layer 23 through an opening provided on the insulating film 30.

The details of the stack 20 are described below. The stack 20 is grown on the substrate main surface 11 of the semiconductor substrate 10 by metal-organic chemical vapor deposition (MOCVD) or the like. Electrons are injected from the n-type semiconductor layer 21 into the active layer 22, and holes are injected from the p-type semiconductor layer 23 into the active layer 22. In the active layer 22, the injected electrons and holes are recombined to generate light. In other words, the nitride semiconductor device shown in FIG. 1 functions as a semiconductor laser.

The n-type semiconductor layer 21 is formed by sequentially stacking a re-grown layer 211, a crack prevention layer 212, an n-type clad layer 213, and an n-type guide layer 214 starting from the side of the semiconductor substrate 10.

The re-grown layer 211 is a GaN layer provided on the substrate main surface 11 of the semiconductor substrate 10. For example, the re-grown layer 211 is formed as an about 2 μm thick GaN layer doped with an n-type dopant such as silicon (Si).

The crack prevention layer 212 is an about 50 nm thick InGaN layer doped with an n-type dopant. The crack prevention layer 212 is composed of an n-type nitride semiconductor film containing indium (In), preferably an InGaN film, so that cracks are prevented from occurring in an Al mixed film formed on the crack prevention layer 212.

The n-type clad layer 213 is formed to provide a light confinement effect of confining light generated at the active layer 22 to between the n-type and p-type clad layers 213 and 233. Accordingly, the n-type clad layer 213 contains AlGaN, which has a higher band gap and a lower refractive index than those of GaN. The n-type clad layer 213 may be a super-lattice layer because the super-lattice structure allows formation of a high crystalline quality clad layer having no cracks. For example, the n-type clad layer 213 can employ a super-lattice structure including a plurality of AlGaN layers doped with an n-type dopant and a plurality of non-doped GaN layers which are alternately stacked on each other.

The n-type guide layer 214 is formed to provide a “carrier confinement effect” of confining carriers (electrons and holes) to the active layer 22. This can increases the efficiency of recombining electrons and holes in the active layer 22. The n-type guide layer 214 is formed by doping a GaN layer with an n-type dopant.

The active layer 22 is a layer to generate light by recombination of electrons and holes and amplify the generated light. The active layer 22 can employ a multiple quantum well (MQW) structure composed of a plurality of InGaN barrier layers and GaN well layers each interposed between the barrier layers. The emission wavelength is set to about 400 to 550 nm, for example, by adjusting the proportion of In. Alternatively, the multiple quantum well structure may be composed in such a manner that each well-layer is an InGaN layer with a proportion of In of not less than 5%, whose band gap is comparatively small, and each barrier layer is a GaN layer, whose band gap is comparatively large.

The p-type semiconductor layer 23 is formed by stacking a p-type cap layer 231, a p-type guide layer 232, a p-type clad layer 233, and a p-type contact layer 234 on the active layer 22.

The p-type cap layer 231 is formed on the active layer 22 as an AlGaN layer doped with a p-type dopant for example, such as magnesium (Mg).

The p-type guide layer 232 is a semiconductor layer to provide the aforementioned “carrier confinement effect”. The p-type guide layer 232 has a band cap smaller than that of the p-type cap layer 231 and is formed by doping a GaN layer with a p-type dopant such as Mg.

The p-type clad layer 233 is formed to provide the above described “light confinement effect”. The p-type clad layer 233 may be composed of a superlattice structure in which a plurality of AlGaN layers and GaN layers doped with a p-type dopant are alternately stacked on each other. For example, about 2 nm thick AlGaN layers and about 2 nm thick GaN layers are alternately stacked on each other to form the p-type clad layer 233 with a thickness of about 0.4 μm. Forming the p-type clad layer 233 of the superlattice structure allows the p-type semiconductor layer 23 to have low resistance.

The p-type contact layer 234 is a low-resistance layer provided to reduce electric resistance between the p-type semiconductor layer 23 and the p-side ohmic electrode 41. The p-type contact layer 234 is formed by doping a GaN layer with a p-type dopant of a high concentration.

By partially removing the upper half of the p-type semiconductor layer 23, a ridge stripe 50 shown in FIG. 1 is formed. For example, the p-type contact and clad layers 234 and 233 are partially removed by etching for formation of the ridge stripe 50. The ridge stripe 50 is formed in consideration of the plane orientation of the semiconductor substrate 10 so that each of the longitudinal end faces of the ridge stripe 50 is composed of a cleavage plane. Specifically, the ridge stripe 50 extends along the m-axis, which is a surface normal to an m-plane of a hexagonal system, and each end face thereof is composed of the m-plane.

Accordingly, the n-type guide layer 214, active layer 22, and p-type guide layer 232 constitute a Fabry-Perot resonator whose resonator end faces are composed of end faces of the ridge stripe 50 at both longitudinal ends. The light generated at the active layer 22 is reciprocated between the end faces of the ridge stripe 50 at the both longitudinal ends (in a resonance direction) to be amplified by stimulated emission. Part of the amplified light is then outputted from the longitudinal end faces to the outside of the nitride semiconductor device as a laser beam.

As shown in FIG. 1, the insulating film 30 covering exposed surfaces of the p-type guide and clad layers 232 and 233 is provided so that the p-side ohmic electrode 41 is in contact with only the p-type contact layer 234 at the top of the ridge stripe 50 (a stripe contact area). Current is therefore concentrated to the ridge stripe 50, thus enabling efficient laser oscillation. The surface of the ridge stripe 50 is covered with the insulating film 30 except an area in contact with the p-side ohmic electrode 41, so that current leakage through the side faces is prevented.

In the example described above, the aluminum-contained nitride semiconductor layers among all the layers included in the stack 20 are the n-type clad layer 213 and p-type cap layer 231, which are the AlGaN layers, and the p-type clad layer 233 having the superlattice structure including the AlGaN and GaN layers alternately stacked. The substrate thickness T of the semiconductor substrate 10 is set so as to satisfy equation (31):

T/860<=(x₁*t₁+x₂*t₂+k*x₃*t₃)<=T/530 (31)

where t₁ and x₁ are thickness and proportion of Al in the n-type clad layer 213, respectively; t₂ and x₂, thickness and Al proportion of the p-type cap layer 231; and t₃ and x₃, thickness and proportion of Al of each AlGaN layer included in the p-type clad layer 233, and k is the number of layers of the AlGaN layer contained in p-type clad layer 233.

According to the nitride semiconductor device of the embodiment of the present invention, the epitaxial structure of the nitride semiconductor layers is optimized, so that the sum S of the products of the proportions of Al and thicknesses of the nitride semiconductor layers containing Al and the substrate thickness T of the semiconductor substrate 10 satisfy the relationship of T/860<=S<=T/530. In the provided nitride semiconductor device, therefore, the stress and warpage caused in the nitride semiconductor layers including the active layer 22 due to internal stress can be reduced while good cleaving characteristics are maintained.

Next, a description is given of a method of manufacturing the nitride semiconductor device according to the embodiment of the present invention. The following method of manufacturing the nitride semiconductor device is just an example, and it is therefore obvious that various types of manufacturing methods can be implemented including modifications thereof.

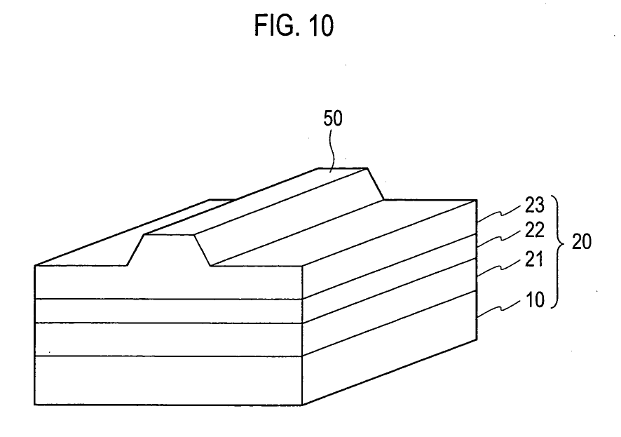

(1) The semiconductor substrate 10 which has a main surface of GaN and is wafer-formed is set in a reaction container of a MOCVD machine. On the semiconductor substrate 10 set to about 1050° C., an about 2 μm GaN film is formed as the re-grown layer 211. At this time, the re-grown layer 211 is doped with Si at a doping concentration of 1×10¹⁸ cm⁻³.
(2) On the re-grown layer 211, the crack prevention layer 212 composed of InGaN doped with Si at a concentration of 5×10¹⁸ cm⁻³ is grown to a thickness of 50 nm. Thereafter, about 100 n-type Al_{0.1}Ga_{0.9}N layers each of which is 2 nm thick and is doped with Si at a concentration of 5×10¹⁸ cm⁻³ and about 100 undoped 20 nm thick GaN layers are alternately stacked on each other to form the n-type clad layer 213 which has a superlattice structure and has a thickness of 0.4 μm. Subsequently, the n-type guide layer 214 which is composed of n-type GaN doped with Si at a concentration of 5×10¹⁸ cm⁻³ and has a thickness of about 0.1 μm is grown on the n-type clad layer 213.
(3) 2.5 nm thick In_{0.2}Ga_{0.8}N layers as the well layers and 5 nm thick In_{0.05}Ga_{0.95}N layers as the barrier layers are alternately stacked on each other to form the active layer 22 with a thickness of about 17.5 nm.
(4) The p-type cap layer 231 composed of p-type Al_{0.3}Ga_{0.7}N doped with Mg as the p-type dopant at a concentration of 1×10²⁰ cm⁻¹ is grown to a thickness of about 30 nm. On the p-type cap layer 231, the p-type guide layer 232 which has a band gap smaller than that of the p-type cap layer 231 and is composed of p-type GaN doped with Mg at a concentration of 1×10²⁰ cm⁻³ is grown to a thickness of about 0.1 μm.
(5) About 2 nm thick p-type Al_{0.1}Ga_{0.9}N layers doped with Mg at a concentration of 1×10²⁰ cm⁻¹ and about 2 nm thick GaN layers doped with Mg at a concentration of 1×10²⁰ cm⁻³ are alternately stacked on each other to form the p-type clad layer 233 of a superlattice structure with a thickness of 0.4 μm. Subsequently, the p-type contact layer 234 composed of an about 15 nm thick p-type GaN layer doped with Mg at a concentration of 2×10²⁰ cm⁻³ is grown.
(6) The semiconductor substrate 10 is annealed at 700° C. in nitrogen atmosphere to further reduce the resistance of the p-type semiconductor layer 23.
(7) After the annealing, the semiconductor substrate 10 is taken out from the reaction container, and an upper part of the p-type semiconductor layer 23 is partially removed by dry etching such as plasma etching as shown in FIG. 10 to form the ridge stripe 50. For example, a photoresist film is applied to the entire surface of the p-type semiconductor layer 23, and a part of the photoresist film to be etched is removed by photolithography to expose a part of the surface of the p-type semiconductor layer 23. The p-type contact and clad layers 234 and 233 are etched using the photoresist film as a mask to form the ridge stripe 50 with a width of about 4 μm. As described above, the ridge stripe 50 is formed so as to extend along the m-axis.
(8) On the upper surface of the p-type semiconductor layer 23, the insulating film 30 is formed by the lift off method or the like. Specifically, after a stripe mask is formed with a photoresist film or the like, an insulator thin film is formed so as to fully cover the p-type clad and contact layers 233 and 234. This insulator thin film is subjected to lift-off to expose only the top of the p-type contact layer 234, thus forming the insulating film 30.
(9) The p-side ohmic electrode 41 is formed on the insulating film 30 so as to be in contact with the exposed top of the p-type contact layer 234. On the p-side ohmic electrode 41, then the p-side bonding electrode 42 is formed.
(10) The semiconductor substrate 10 is subjected to polishing at the rear surface to be thin. Specifically, the semiconductor substrate 10 is thinned by mechanical polishing with a diamond stone to a substrate thickness of for example not more than 100 μm according to a desired substrate thickness T, preferably to a substrate thickness about 10 μm thicker than the final substrate thickness T. Subsequently, a work-affected layer generated by the mechanical polishing is removed by polishing using diamond slurry having two particle sizes. The product is then mirror-finished by chemical mechanical polishing (CMP). Through the aforementioned steps, the semiconductor substrate 10 is thinned to the desired substrate thickness T, for example 80 μm. The substrate thickness T is set so that the substrate thickness T and the sum S of the products of the proportions of Al and thicknesses of all the Al-contained nitride semiconductor layers included in the stack 20 satisfy the relationship of equation (1).
(11) The n-side ohmic electrode 51 is formed on the rear surface of the semiconductor substrate 10. The semiconductor substrate 10, which is wafer-formed, is subjected to cleavage at planes vertical to the direction that the stripe 50 extends (planes corresponding to the resonator end faces), or m-plane, into bar form. In other words, a wafer including a plurality of nitride semiconductor devices arranged in a matrix is divided into a plurality of bar-formed wafer pieces including the nitride semiconductor devices aligned along the cleavage planes.
(12) On the resonator end faces of the semiconductor substrate 10 exposed as the cleavage planes, dielectric multilayer films composed of for example silicon oxide (SiO₂) and zirconia (ZrO₂) are formed by electron cyclotron resonance (ECR) deposition or the like. At this time, it is configured that one of the resonance end faces has a small reflectance and the other has a large reflectance.
(13) The bar-formed pieces of the semiconductor substrate 10 are cut along the direction that the ridge stripe 50 extends into chip form, thus forming the nitride semiconductor device shown in FIG. 1.

In such a manner, a Fabry-Perot resonator whose resonator end faces are composed of both longitudinal end faces of the ridge stripe 50 (in the resonance direction) is formed. A part of light amplified by the Fabry-Perot resonator is outputted through the resonator end face (an output face) with a smaller reflectance to the outside of the nitride semiconductor device as a laser beam.

The insulating film 30 can be for example a ZrO₂ film, a SiO₂ film, or the like.

The p-side ohmic electrode 41 is composed of for example a stack of palladium (Pd)-gold (Au) or the like. The p-side bonding electrode 42 can be composed of for example a stack of nickel (Ni)—Au, a stack of Ti—Au, or the like.

The n-side ohmic electrode 51 can be a stack of titanium (Ti)—Al—Au or the like. The n-side ohmic electrode 51 is placed on a wiring pattern on a not-shown wiring board. The wiring board and the p-side bonding electrode 42 are electrically connected by a bonding wire or the like.

According to the aforementioned method of manufacturing a nitride semiconductor device according to the embodiment of the present invention, it is possible to manufacture a nitride semiconductor device whose nitride semiconductor layer has an epitaxial structure optimized with respect to the substrate thickness T so that the sum S of the products of the proportion of Al and thickness of the nitride semiconductor layers containing Al and the substrate thickness T of the semiconductor substrate 10 satisfy: T/860<=S<=T/530. This can provide a nitride semiconductor device in which the stress and warpage, which are caused in the nitride semiconductor layers due to internal stress, can be reduced while good cleaving characteristics are maintained.

A nitride semiconductor device manufactured by the aforementioned method is set in a heat sink with the junction up so that the rear surface of the semiconductor substrate 10 faces the heat sink for laser oscillation. As a result, it is confirmed that the nitride semiconductor device kept oscillating at room temperature (oscillation wavelength: 405 nm, threshold current density: 2.5 kA/cm², and the threshold voltage: 4.5 V) and provided a device lifetime of 500 hours or more.

### OTHER EMBODIMENTS

It should not be understood that the description and the drawings, which form a part of the disclosure of the above-described embodiment, limit this invention. From this disclosure, a variety of alternative embodiments, examples and operation technologies will be obvious for those skilled in the art.

In the above description of the embodiment, the example of the nitride semiconductor layer including the ridge stripe 50 is shown. However, the nitride semiconductor layer does not necessarily include a ridge stripe. The nitride semiconductor device is not limited to a laser diode and may be an LED or the like.

As described above, it is obvious that the present invention includes various embodiments and the like not described above. Accordingly, the technical scope of the present invention is determined by only the invention elements according to claims appropriate from the viewpoint of the above explanation.

What is claimed is:

1. A nitride semiconductor device comprising:
a semiconductor substrate composed of gallium nitride; and
a stack which is provided on the semiconductor substrate and includes at least one nitride semiconductor layer containing aluminum, wherein
substrate thickness T of the semiconductor substrate and a sum S of products of proportions of aluminum and thicknesses of all of the nitride semiconductor layer containing aluminum among the stack satisfy a relationship of:
T/860<=S<=T/530

2. The nitride semiconductor device of claim 1, wherein the stack further includes an active layer containing indium.

3. The nitride semiconductor device of claim 2, wherein the stack has a structure including an n-type semiconductor layer, the active layer, and a p-type semiconductor layer stacked in this order, and at least one of nitride semiconductor layers included in the n-type and p-type semiconductor layers is a nitride semiconductor containing aluminum.

4. The nitride semiconductor device of claim 2, wherein a face through which light generated at the active layer is outputted is a cleavage plane.

5. A semiconductor laser, comprising:
a semiconductor substrate composed of gallium nitride; and
a stack which is provided on the semiconductor substrate and includes at least one nitride semiconductor layer containing aluminum, wherein
substrate thickness T of the semiconductor substrate and a sum S of products of proportions of aluminum and thicknesses of all of the nitride semiconductor layer containing aluminum among the stack satisfy a relationship of:
T/860<=S<=T/530
and a chip width vertical to a resonance direction of a laser beam and a thickness direction of the semiconductor substrate is not less than 60 μm and not more than 80 μm.

6. The semiconductor laser of claim 5, wherein the stack further includes an active layer containing indium.

7. The semiconductor laser of claim 6, wherein the stack has a structure including an n-type semiconductor layer, the active layer, and a p-type semiconductor layer stacked in this order, and at least one of nitride semiconductor layers included in the n-type and p-type semiconductor layers is a nitride semiconductor containing aluminum.

8. The semiconductor laser of claim 6, wherein a face through which light generated at the active layer is outputted is a cleavage plane.
